(19) United States
(12) Patent Application Publication
(10) Pub. No.: US 2016/0152930 A1
(43) Pub. Date: Jun. 2, 2016

(54) Stripping and Cleaning Compositions for Removal of Thick Film Resist

(71) Applicant: Air Products and Chemicals, Inc., Allentown, PA (US)

(72) Inventors: Matthew I. Egbe, West Norriton, PA (US); Aiping Wu, Macungie, PA (US); Madhukar Bhaskara Rao, Carlsbad, CA (US)

(73) Assignee: Air Products and Chemicals, Inc., Allentown, PA (US)

(21) Appl. No.: 15/018,564

(22) Filed: Feb. 8, 2016

Related U.S. Application Data
(63) Continuation of application No. 14/043,330, filed on Oct. 1, 2013.
(60) Provisional application No. 61/841,596, filed on Jul. 1, 2013.
(60) Provisional application No. 61/710,901, filed on Oct. 8, 2012.

(51) Int. Cl. C11D 11/00; C11D 7/50; H01L 21/02; C11D 7/34; C11D 7/26; C11D 7/06; C11D 7/32

(52) U.S. Cl. CPC C11D 11/0047; C11D 7/06; C11D 7/5009; C11D 7/5013; C11D 7/3209; C11D 7/34; C11D 7/265; C11D 7/5022; H01L 21/0206

(57) ABSTRACT

Stripping and cleaning compositions suitable for the removal of film resists include about 2-55% by weight of at least one alkanolamine or at least one morpholine or mixtures thereof; about 20-94% by weight of at least one organic solvent; and about 0.5-60% by weight water based on the total weight of the composition.

### CROSS REFERENCE TO RELATED APPLICATIONS

This application claims the benefit of priority to earlier filed U.S. patent application Ser. No. 14/043,330, filed on Oct. 1, 2016, U.S. provisional patent application 61/841,596, filed on Jul. 1, 2013 and U.S. provisional patent application 61/710901, filed on Oct. 8, 2012. The content of each priority application is incorporated herein by reference in its entirety.

### BACKGROUND OF THE INVENTION

Numerous steps are involved in the fabrication of microelectronic structures. Within the manufacturing scheme of fabricating integrated circuits, selective removal of resist materials is sometimes required. Historically, a number of vastly different types of processes, to selectively remove material, have been successfully utilized to varying degrees.

In the manufacture of semiconductors and semiconductor microcircuits, it is frequently necessary to coat substrate materials with a polymeric organic substance. Examples of such substrate materials includes titanium, copper, silicon dioxide coated silicon wafer which may further include metallic elements of titanium, copper, and the like. Typically, the polymeric organic substance is a resist film such as, for example, a photoresist. This photoresist film may form an etch mask upon development after exposure to light. In subsequent processing steps, at least a portion of the photoresist is removed from the surface of the substrate. Common methods of removing photoresist from a substrate are by wet chemical or dry means. The wet chemical compositions (e.g., “wet” stripping) are formulated to remove the photoresist from the substrate, but should do so without corroding, dissolving, and/or dulling the surface of any metallic circuitry; chemically altering the inorganic substrate; and/or attacking the substrate itself.

Applications for thick photoresist films continue to gain importance for microelectrical mechanical systems (MEMS), giant magneto-resistive (GMR) read write head manufacture, and wafer bumping for flip chip applications. The advanced packaging market is growing at a compound annual rate of thirty percent. The solder bump area is the largest component of this market. For these applications, thick photoresists need to offer vertical sidewalls, excellent adhesion to the substrate, and resistance to stress-induced cracking and underplating. When used for wafer bumping processes, thick photoresist layers have to act as an effective photoresist mold as well as offer resistance to photoresist deformation during electrodeposition to ensure the precise location and geometry of the pillars interconnecting the parts of the finished device. Today there is a rapid increase in the pin counts of most solder bump applications. The corresponding reduction in bump pitch is making conventional “mushroom” type over plating impractical for high bump count devices. Elimination of the umbrella requires even thicker photoresist layers since the entire solder volume buildup is contained in the stud defined by the photoresist mold.

This demand for increased resolution and high aspect ratio leads to great lithographic challenges. For example, the photoresist aspect ratio for thin film heads (greater than 10:1) is actually larger than the aspect ratio used in chip making. The photoresist films can be so thick that substantial residual solvent remains after baking, and the amount of residual casting solvent in the photoresist film is known to affect many lithographic properties such as photospeed, contrast, critical dimension, and thermal behavior. The solvent also acts as a plasticizer and can affect the glass transition temperature (Tg) of polymers. Dissolution rates of photoresist films also depend greatly on the amount of residual casting solvent. So, even though the required resolution is typically not limited by optics, these thick films pose a processing challenge that is different from but no less demanding than that of leading edge sub-quarter micron lithographies.

The bulk of the photoresists used currently for thick film applications are positive-tone diazonaphthoquinone (DNQ)/Novolak photoresists. Compared with front end processing requiring much thinner photoresists, processing thicker photoresists is substantially more challenging; they require longer bake and development and exhibit slower photospeeds. In addition, coating uniformity and control of the size of the edge bead become more difficult to achieve.

Traditionally, the exposure time is the limiting factor since the exposure system is the most expensive part of the cell. However, with thick photoresist films the track developer process can be the limiting factor with the develop time in excess of 5 minutes. By improving the develop rate, the total exposure and develop time will decrease, reducing the total cost of ownership. However, changing develop conditions can impact the photoresist performance including critical dimension (CD) control, profile and aspect ratios.

Accordingly, it would therefore be desirable to provide stripping or cleaning compositions effective for efficiently and effectively removing thick film resists without harming the underlying substrate structure.

### SUMMARY OF THE INVENTION

The present invention satisfies this need by providing stripping and cleaning compositions, which are particularly suitable for the removal of thick film resists, under desirable processing conditions (e.g., temperatures of 75° C. or less for periods of time of 60 min. or less or 15 min. or less), and with little or no damage to the underlying substrate (e.g., minimal or no etching of the metal post substrate). The compositions are designed for stripping of both wet and dry films.

According to one aspect of the invention, the composition includes about 5-30% by weight of at least one alkanolamine or at least one morpholine or mixtures thereof based on the total weight of the composition; about 20-80% by weight of at least one organic solvent based on the total weight of the composition; and about 0-60% by weight water based on the total weight of the composition.

According to another aspect of the invention, the composition includes about 2-55% or 2-30% or 10-20% or 15-20% by weight of at least one alkanolamine or at least one morpholine or mixtures thereof based on the total weight of the composition; about 20-94% or 40-90% or 45-65% or 40-65% by weight of at least one organic solvent based on the total weight of the composition; and about 0.5-60% or about 1-60% or 1-55% or 10-45% or 10-40% by weight water based on the total weight of the composition.

Any composition of this invention may additionally comprise one or more components to tune the electrochemical properties of the composition (e.g. amino acid) from about 0.001 to about 1% or about 0.005 to about 0.1% by weight based on the total weight of the composition.

The alkanolamine may include, for example, monoethanol amine (MEA), N-methylethanolamine (NMEA), triethanolamine (TEA), and mixtures thereof.

The morpholine may include aminoalkylmorpholine (e.g. N-3-aminopropylmorpholine), and others.

Preferably, the organic solvent comprises at least one, that is, one or a mixture of two or more, water soluble or water miscible organic solvent. Suitable solvents may include, for example, dimethylsulfoxide, glycol ethers, such as tri(propylene glycol) methyl ether (t-PGME), propylene glycol monophenyl ether, tripropylene glycol monobutyl ether, (TPnB) or hydric alcohols having 2 to 8 carbon atoms, such as tetrahydrofufuryl alcohol (THFA) and benzyl alcohol or diols, such as glycols, such as, dipropylene glycol.

The composition may further include one or more additional ingredients, such as one or more hydroxides and/or one or more corrosion inhibitors. The one or more hydroxides, may be one or more metal hydroxides, such as potassium hydroxide, and/or one or more quaternary ammonium hydroxides, such as tetraethylammonium hydroxide. The one or more corrosion inhibitors may be aminobenzothiazole (ABT) or 2-mercaptobenzimidazole; or an organic acid, such as gallic acid or isophthalic acid or tannic acid or mixtures thereof.

The one or more hydroxides may be present in any of the compositions of this invention in any amount, for example, from about 0.1% to about 10% or from about 0.1% to about 6% by weight, or from about 0.1% to about 3.5%, or from about 0.2% to about 5%, or from 0.1 to 0.2% by weight.

The one or more corrosion inhibitors may be present in any of the compositions of this invention in any amount, for example, from about 0.5% to about 10% or from about 1.0% to about 6% by weight, or from about 1% to about 5.5%, or from about 1.0% to about 3% by weight. In some embodiments of the compositions of this invention, the one or more corrosion inhibitors are present at a greater weight percent than the one or more hydroxides. Alternatively, in some embodiments, when an amino acid is present, no corrosion inhibitor may be present in the composition.

According to one embodiment of the invention, the composition includes about 2-25% or 10-20% or 15-20% by weight of at least one alkanolamine (e.g., MEA) and/or at least one morpholine (e.g aminopropyl morpholine) based on the total weight of the composition; about 40-80% or 50-75% or 40-65% by weight of the organic solvent (e.g., THFA, DMSO, glycol ether) (may be mixtures of solvents) based on the total weight of the composition; about 0-1.5% or 0.05-3% or 1-5.5% by weight of a corrosion inhibitor (e.g, thiazole (e.g., ABT) or imidazole or catechol (e.g TBC) or isophalic acid or mixtures thereof); about 0-2% or 1-3% or 1-2% or 0.1-5% or 0.1-3.5% by weight of at least one hydroxide (e.g., potassium hydroxide or choline hydroxide or mixtures thereof); and about 0-60% or 1-60% or 1-50% or 10-40% by weight water based on the total weight of the composition.

According to another embodiment of the invention, the composition comprises or consists essentially of about 5-30% or 15-20% by weight of an alkanolamine (e.g., MEA) and/or morpholine (e.g aminopropyl morpholine) based on the total weight of the composition; about 20-80% or 40-65% by weight of a water soluble or water miscible organic solvent (e.g., THFA) based on the total weight of the composition; about 0.1-1.5% or 1-5% by weight of at least one thiazole (e.g., ABT) or imidazole or catechol or mixtures thereof; about 0.1-2% or 0.1-4% by weight of a hydroxide (e.g., potassium hydroxide); about 0-5% or 0.5-5% or 0.5-3% by weight of an organic acid (e.g., gallic acid or isophthalic acid); and about 0-60% or 1-60% or 10-40% by weight water based on the total weight of the composition.

According to another embodiment of the invention, the composition includes from about 2 to about 8% or from about 2 to about 5% by weight of one or more alkanolamine (e.g., MEA) or one or more morpholine (e.g. N-(3-aminopropyl)morpholine) or mixtures of alkanolamine or morpholine based on the total weight of the composition; from about 70 to about 94% or from about 75 to about 92% by weight of the organic solvent (may be mixtures of solvents) (e.g., THFA, glycol ether, and/or glycol or other alcohols) based on the total weight of the composition; from 0 to about 1.5% or from about 0.5 to about 1.5% by weight of a corrosion inhibitor that may be at least one of a thiazole (e.g., ABT) or an imidazole (e.g. mercaptobenzimidazole) from 0 to about 5% or from about 0.5 to about 4% by weight of a hydroxide (e.g., potassium hydroxide or tetraethylammonium hydroxide); and from about 0 to about 20%, or from about 2 to about 17% by weight water based on the total weight of the composition. The hydroxide may be at least one of a metal hydroxide or at least one or a quaternary ammonium hydroxide or mixtures thereof.

According to another embodiment of the invention, the composition comprises from about 10 to about 20% or from about 15 to about 20% by weight of alkanolamine (e.g., MEA) and/or morpholine (e.g. N-(3-aminopropyl)morpholine) or mixture thereof based on the total weight of the composition; from about 45 to about 80% or from about 50 to about 60% or from about 40 to about 65% by weight of the organic solvent (may be mixtures of solvents) (e.g., THFA, glycol ether, and/or glycol or other alcohols) based on the total weight of the composition; from 1 to about 5.5% or from about 0.5 to about 1.5% by weight of one or more corrosion inhibitors that may be at least one thiazole (e.g., ABT) or at least one imidozole (or mixtures thereof); from 0 to about 3.5% or from about 0.1 to about 3.5% or from about 0.1 to about 1.0% by weight of one or more hydroxides (e.g., potassium hydroxide or other metal hydroxides or quaternary ammonium hydroxides (e.g. choline hydroxide or tetraethylammonium hydroxide) or mixtures thereof); and from 10 to about 35%, or from about 10 to about 40% or from about 20 to about 35% by weight water based on the total weight of the composition. In some embodiments, the composition may be free of (not include) or be substantially free (that is include less than 0.001% or less than 0.01%) of one or more of the following in any combination dimethyl acetamide and/or other acetamides and/or dimethylsulfoxide and/or other sulfoxides and/or N-methylpyrrolidone and/or other pyrrolidones, and/or quaternary hydroxides (and/or quaternary ammonium hydroxides) and/or potassium hydroxide and/or metal hydroxides and/or halogens and/or fluorine and/or chlorine and/or oxidizers (e.g. H₂O₂ or nitric acid) and/or hydroxylamines and/or formamides.

The composition may be basic having a pH of about 8.0 or higher, preferably about 8.5 or higher.

According to another embodiment of the invention, a method of stripping or removing a film resist, particularly a thick film resist in a wet or dry process includes applying to the film resist a composition in accordance with the present invention.

### DETAILED DESCRIPTION OF THE INVENTION

The compositions, effective for stripping, cleaning, or removing film resists, include at least one alkanolamine or at least one morpholine or mixtures thereof; at least one organic solvent; and optionally water.

As used herein and in the claims, the terms “comprising,” “comprises,” “including,” and “includes” are inclusive or open-ended and do not exclude additional unrecited elements, composition components, or method steps. Accordingly, these terms encompass the more restrictive terms “consisting essentially of” and “consisting of.” Therefore, any use of “comprising,” “comprises,” “including,” and “includes” may be substituted with “consisting essentially of” and/or “consisting of.” Unless specified otherwise, all values provided herein include up to and including the endpoints given, and the values of the constituents or components of the compositions are expressed in weight percent of each ingredient in the composition.

The stripping and cleaning composition includes at least one alkanolamine or at least one morpholine or mixtures thereof. The alkanolamine preferably includes hydroxy and amino functional groups on an alkane backbone (e.g., comprising 2-5 carbon atoms). The amino group may be a primary, secondary, or tertiary amino group. Ethanolamines and propanolamines, such as monoethanolamine, diethanolamine, triethanolamine, mono-isopropanolamine, di-isopropanolamine, tri-isopropanolamine, and mixtures thereof may be particularly preferred. In an exemplary embodiment, the alkanolamine comprises an ethanolamine, such as monoethanol amine (MEA), N-methylethanolamine (NMEA), triethanolamine (TEA), and mixtures thereof. Preferably, the alkanolamine includes monoethanol amine (MEA). Example of morpholines include: aminoalkyl morpholine, where the alkyl group may have 1 to 5 carbons, such as, N-3 aminopropylmorpholine, N-3 aminoethylmorpholine, and 2(Aminomethyl)morpholine.

The at least one alkanolamine and/or the at least one morpholine, each alone or in mixtures may be present in any of the compositions of this invention in any amounts ranging from about 2 to about 60% or from 3 to about 55% or from about 2 to about 30% or from about 5% to about 30%, or from about 10% to about 20%, or from about 15% to about 20% or from about 2% to about 8% or from about 2% to about 5% by weight based on the total weight of the composition. In other embodiments, a mixture of one or more alkanolamines and one or more morpholines may be present in total weight amounts ranging from about 2 to about 60% or from 3 to about 55% or from about 2 to about 30% or from about 5% to about 30%, or from about 10% to about 20%, or from about 15% to about 20% or from about 2% to about 8% or from about 2% to about 5% by weight based on the total weight of the composition.

Examples of useful morpholines include N-(3-aminopropyl)morpholine, N-3 aminoethylmorpholine, and 2(Aminomethyl)morpholine. In other embodiments, the morpholine may be present from about 2 to about 60% or from about 3 to about 55% or from about 15 to about 20 or from 3 to 25% by weight alone or in combination with the alkanolamine. The alkanolamine and/or morpholine functions primarily (1) as a solvent to aid in the removal of the resist; and (2) as a caustic material to increase the pH, which otherwise would be increased by higher levels of caustic, for example, KOH and NaOH or quaternary ammonium hydroxide. Low levels of metal ions are desired in compositions according to the present invention.

The organic solvent preferably includes at least one or mixtures of more than one water soluble or water miscible organic solvent. As used herein, water soluble or water miscible organic solvents include solvents that are able to mix with water and each other and form a homogeneous solution at standard temperature and pressure. Examples of water soluble or water miscible organic solvents include, but are not limited to, ethylene glycol, propylene glycol, dipropylene glycol, 1,4-butanediol, tripropylene glycol methyl ether, tripropylene glycol monobutyl ether, propylene glycol propyl ether, diethylene glycol n-butyl ether, hexyloxypropylamine, poly(oxyethylene)diamine, dimethylsulfoxide, tetrahydrofurfuryl alcohol, glycerol, alcohols (e.g. benyl alcohol), sulfoxides, or mixtures thereof. Preferred solvents are alcohols, diols, or mixtures thereof. Particularly preferred solvents include glycol ethers or hydric alcohols having 2 to 8 carbon atoms or sulfoxides (e.g. dimethylsulfoxide), and mixtures (e.g. of two more or three or more) thereof, for example.

Examples of glycol ethers include, for example, ethylene glycol monomethyl ether, ethylene glycol monoethyl ether, ethylene glycol monobutyl ether, ethylene glycol dimethyl ether, ethylene glycol diethyl ether, diethylene glycol monomethyl ether, diethylene glycol monoethyl ether, diethylene glycol monopropyl ether, diethylene glycol monoisopropyl ether, diethylene glycol monobutyl ether, diethylene glycol monolisobutyl ether, diethylene glycol monobenzyl ether, diethylene glycol dimethyl ether, diethylene glycol diethyl ether, triethylene glycol monomethyl ether, triethylene glycol dimethyl ether, polyethylene glycol monomethyl ether, diethylene glycol methyl ethyl ether, ethylene glycol monomethyl ether acetate, ethylene glycol monoethyl ether acetate, propylene glycol methyl ether acetate, propylene glycol monomethyl ether, propylene glycol dimethyl ether, propylene glycol monobutyl ether, propylene glycol monopropyl ether, dipropylene glycol monomethyl ether, dipropylene glycol monopropyl ether, dipropylene glycol monoisopropyl ether, dipropylene glycol monobutyl ether, dipropylene glycol diisopropyl ether, tripropylene glycol monomethyl ether, tripropylene glycol monobutyl ether, 1-methoxy-2-butanol, 2-methoxy-1 -butanol, 2-methoxy-2-methylbutanol, 1,1 -dimethoxyethane and 2-(2-butoxyethoxy) ethanol. In an exemplary embodiment, the glycol ether includes tri(propylene glycol) methyl ether (t-PGME).

A suitable monohydric alcohol having one hydroxy group, 2 to 8 carbon atoms, and optionally, a heterocyclic compound, includes tetrahydrofufuryl alcohol (THFA). THFA is particularly preferred because it is biodegradable and water-miscible with high solvency. Additionally, THFA is not listed as a carcinogen and is not classified as a hazardous waste.

The solvent functions primarily to dissolve the organic polymer in the resist layer, thereby removing the layer from the substrate.

It is believed that, for most applications, the amount of organic solvent will comprise from about 5% to about 95% or from about 5% to about 80% by weight of the composition. In some embodiments, the solvent may comprise from about 20% to about 80% by weight, or from about 50% to about 75% by weight or from about 50% to about 60% by weight of the composition. In alternative embodiments, the compositions may comprise from about 20 to about 50% or from about 40 to about 60% or from about 40 to about 65% or 45 to about 80% or from about 70% to about 95% or about 75% to about 94% by weight of the composition. Often the compositions having about 70% to about 95% by weight organic solvent comprise more than one organic solvent, although mixtures of solvents may be used in any weight percent. Preferred mixtures of solvents comprise at least one glycol ether, at least one glycol and optionally an alcohol. (Examples of mixtures of organic solvents include proplylene glycol monophenylether with dipropylene glycol; and tripropylene glycol monobutyl ether with both benzyl alcohol and dipropylene glycol).

In one preferred embodiment, the compositions of the present invention may be free or substantially free of dimethyl acetamide (DMAC) as the solvent. Cleaning compositions containing dimethyl acetamide (DMAC) are used widely for removing residue from semiconductor substrates. DMAC is particularly suitable for such applications because it is highly polar, which makes it an excellent solvent for organic residues. DMAC is also desirable because it has a high flashpoint, it is water soluble, it has a low viscosity, and it is relatively inexpensive. Unfortunately, however, DMAC is classified as a toxic material in both the United States and in Europe. In this regard, DMAC has a National Fire Protection Association (NFPA) health rating of 2 and its Material Safety Data Sheet (MSDS) indicates that it is easily absorbed through the skin. Toxicity data also suggests that DMAC may be an embryotoxin and, as such, its use has been discouraged in Europe and has received extensive scrutiny in the United States and Asia. As a result, the electronics industry, for example, avoids cleaning compositions that include DMAC. Accordingly, the preferred compositions described herein preferably do not include DMAC.

In other embodiments, the compositions of the present invention may be free or substantially free of dimethylsulfoxide (DMSO) and/or N-methylpyrrolidone (NMP) and/or other polar aprotic solvents as the solvent component.

The composition may optionally include water. In certain embodiments, the compositions are aqueous-based or semi-aqueous and, thus, comprise water. The water may function in various ways such as, for example, to dissolve one or more components, as a carrier of the components, as a viscosity modifier, and as a diluent. Preferably, the water employed in the cleaning composition is de-ionized (DI) water. In other embodiments, the compositions do not include any water or negligible amounts of water and are only solvent-based.

It is believed that, for most applications, water will comprise, for example, from about 0 to about 60% or from about 1 to about 55% or from about 1 to about 60% by weight of water. Preferred embodiments of the present invention could comprise from about 2 to about 40% or from about 5 to about 40% or from about 10 to about 40% by weight of water. Other preferred embodiments of the present invention could comprise from about 10 to about 35% by weight of water. Yet other preferred embodiments of the present invention could comprise from about 20% to about 35% or from about 25% to about 35% by weight of water. Still other preferred embodiments of the present invention could comprise from about 23% to about 33% by weight of water. Other embodiments may comprise from about 1% to about 20% or about 2% to about 17% by weight water. Still other preferred embodiments of the present invention could include water in an amount necessary to achieve the desired weight percent of the other ingredients. In other words, the remainder of the composition may include water when the composition is aqueous or semi-aqueous. In some embodiments, comprising solvent and water, the solvent and water may be present between from about 40 to 90% or from about 70 to 85% by weight based on the total weight of the composition. In some of the embodiments, the solvent is present at a greater weight percentage than water. In some embodiments, the solvent is present at greater than 1.5 or greater than 2 times the weight percent of the water present in the composition. Additionally or alternatively, in some embodiments of the composition of this invention, the weight percent of solvent present may be greater than the amount of the alkanolamine and/or morpholine present and in some embodiments may be greater than 2 times, and for some embodiments, between 2 and 6 times, and for still other embodiments between 2 and 4 times, the weight percent of the alkanolamine and/or morpholine present.

The composition may further include at least one hydroxide, preferably a non-toxic hydroxide, for example a metal hydroxide, such as potassium hydroxide, calcium hydroxide, ammonium hydroxide or quaternary ammonium hydroxide.

In an exemplary embodiment, the hydroxide is potassium hydroxide, which may be used as an aqueous solution, for example a 20% aqueous solution. The metal hydroxide may be present in any of the compositions of this invention in amounts ranging from about 0% to about 5%, or from about 0.01% to about 5% or from about 0.01% to about 4%, or from about 0.9 to about 4% or from about 0.01% to about 0.8%, or from about 0.04% to about 0.5%, or from about 0.1% to about 0.2% by weight-based on the total weight of the composition. More preferably, the metal hydroxide is present, but in an amount not greater than 0.5% by weight. In certain preferred compositions, the metal hydroxide is present at about 0.1 to 0.4% by weight.

In some embodiments, the hydroxide does not comprise one or more quaternary compounds (that is it is free or substantially free of quaternary ammonium compounds); however, in some embodiments quaternary ammonium compounds may be useful as the hydroxide in amounts for example, between from about 0.1% to about 6% or from about 0.1% to about 5% by weight of the composition or from about 0.9% to about 4% by weight of the composition. The quaternary ammonium compounds may be used alone or in mixtures with one or more other quaternary ammonium hydroxides, one or more ammonium hydroxides and one or more metal hydroxides. In alternative embodiments, the compositions are free or substantially free of metal hydroxides. In some embodiments, the compositions are free of or substantially free of hydroxides. In some embodiments, when one or more hydroxides are used together in the composition of this invention, the total weight percent of hydroxides may be between from about 0.1% to about 6% or from about 0.1% to about 5% or from about 0.9% to about 4% by weight of the composition. In some embodiments, when one or more metal hydroxides are present in a composition with one or more ammonium hydroxides or quaternary ammonium hydroxides, then the one or more metal hydroxides may be present at less than the weight of the total weight of the one or more ammonium hydroxides or quaternary ammonium hydroxides in the composition or less than 50% or less than 75% or less than 90% of the total weight of the one or more ammonium hydroxides or quaternary ammonium hydroxides in the composition.

Examples of useful quaternary ammonium compounds may be those compounds having the formula [N-R¹R²R³R⁴]⁺OH⁻ wherein R¹, R², R³, and R⁴ are each independently an alkyl group, a hydroxyalkyl group, and combinations thereof. The term “alkyl” as used herein refers to straight or branched chain unsubstituted hydrocarbon groups of 1 to 20 carbon atoms, or from 1 to 8 carbon atoms, or from 1 to 4 carbon atoms. Examples of suitable alkyl groups include methyl, ethyl, propyl, isopropyl, butyl, and tertbutyl. The term “hydroxyalkyl” as used herein refers to straight or branched unsubstituted hydroxyl-group-containing hydrocarbon of from 1 to 20 carbon atoms, or from 1 to 8 carbon atoms, or from 1 to 4 carbon atoms, or from 1 to 3 carbons or 1 to 2 carbons. Examples of suitable hydroxylalkyl groups include hydroxylethyl and hydroxypropyl. Examples of suitable quaternary ammonium hydroxide compounds include tetramethylammonium hydroxide (TMAH), tetraethylammonium hydroxide (TEAH), tetrabutylammonium hydroxide (TBAH), tetrapropylamonium hydroxide, trimethylethylammonium hydroxide, (2-hydroxyethyl)trimethylammonium hydroxide, (2-hydroxyehyl)triethylammonium hydroxide, (2-hydroxyethyl)triporpylammonium hydroxide, (1-hydroxypropyl)trimethylammonium hydroxide, ethyltrimethylammonium hydroxide, diethyldimethylammonium hydroxide and benzyltrimethylammonium hydroxide.

The cleaning composition of the present invention also optionally includes a corrosion-inhibitor or mixtures of 2 or more corrosion inhibitors. The use of a corrosion-inhibitor may be preferred when the composition is used to clean a film resist on a metallic substrate. Examples of corrosion-inhibitors include aromatic hydroxyl compounds, acetylenic alcohols, carboxyl group-containing organic compounds and anhydrides thereof, and triazole and thiazole and imidazoles compounds.

Exemplary aromatic hydroxyl compounds useful as corrosion inhibitors in the compositions of this invention, include phenol, cresol, xylenol, pyrocatechol, t-butylcatechol, resorcinol, hydroquinone, pyrogallol, 1,2,4-benzenetriol, salicyl alcohol, p-hydroxybenzyl alcohol, o-hydroxybenzyl alcohol, p-hydroxyphenethyl alcohol, p-aminophenol, m-aminophenol, diaminophenol, amino resorcinol, p-hydroxybenzoic acid, o-hydroxybenzoic acid 2,4-dihydroxybenzoic acid, 2-5-dihydroxybenzoic acid, 3,4-dihydroxybenzoic acid and 3,5-dihydroxybenzoic acid.

Exemplary acetylenic alcohols useful as corrosion inhibitors in the compositions of this invention, include 2-butyne-1,4-diol, 3,5-dimethyl-1-hexyn-3-ol, 2 methyl-3-butyn-2-ol, 3-methyl-1-pentyn-3-ol, 3,6-dimethyl-4-octyn-3,6-diol, 2,4-7,9-tetramethyl-5-decyne-4,7-diol and 2,5-dimethyl-3-hexyne 2,5-diol.

Exemplary carboxyl group-containing organic compounds and anhydrides thereof useful as corrosion inhibitors in the compositions of this invention, include formic acid, acetic acid, propionic acid, butyric acid, isobutyric acid, oxalic acid, malonic acid, succinic acid, glutaric acid, maleic acid, fumaric acid, benzoic acid, phthalic acid, isophthalic acid, 1,2,3-benzenetricarboxylic acid, glycolic acid, lactic acid, maleic acid citric acid, acetic anhydride, tannic acid and salicylic acid.

Exemplary triazole compounds useful as corrosion inhibitors in the compositions of this invention, include benzotriazole, o-tolyltriazole, m-tolyltriazole, p-tolyltriazole, carboxybenzotriazole, 1-hydroxybenzotriazole, nitrobenzotriazole and dihydroxypropylbenzotriazole.

Exemplary thiazole compounds useful as corrosion inhibitors in the compositions of this invention, include 2-aminobenzothiazole, 2-mercaptobenzothiazole; 2,5-dimercapto-1,3,4-thiazole; and 2-aminothiazole.

Exemplary imidazole compounds useful as corrosion inhibitors in the compositions of this invention, include mercapto benzimidizole, 1-(-tolyl)-4-methylimidazole, 1-phenyl-4-methylimidazole, 4-methyl-5-hydroxymethylimidazole, 2-merceto-1-methylimidazole, 4-methylimidazole, benzimidazole, and 2-mercapto benzimidazole.

Preferred inhibitors are aminobenzothiazole, aminobenzene sulfonic acid, catechol, t-butylcatechol, gallic acid, isophthalic acid, tannic acid, benzotriazole, benzamidazole, (e.g. 2-mecaptobenzimidazole, pyrogallol, 4-methyl catechol, fumaric acid and diethylhydroxylamine (DEHA) and mixtures thereof. It is preferred that an inhibitor other than benzotriazole be used when cleaning a substrate comprising copper because benzotriazole has a tendency to bind to copper.

In an exemplary embodiment, the corrosion inhibitor is selected from the group consisting of thiazoles, organic acid salts, catechol, benzotriazole (BZT), benzimidazole, resorcinol, other phenols, acids or triazoles, maleic anhydride, phthalic anhydride, catechol, pyrogallol, esters of gallic acid, carboxybenzotriazole, fructose, ammonium thiosulfate, glycine; tetramethylguanidine, iminodiacetic acid, dimethylacetoacetamide, trihydroxybenzene, dihydroxybenzene, salicyclohydroxamic, and mixtures thereof. In a preferred embodiment, the corrosion inhibitor includes 2-aminobenzothiazole (ABT) or 2-mercaptobensimidazole, alone or in a mixture with other corrosion inhibitors.

It is believed that for most applications, one or more corrosion-inhibitors will comprise from about 0 to about 10% by weight of the composition; preferably one or more corrosion inhibitors comprise from about 0.1 to about 6% by weight. In some embodiments the preferred range for corrosion inhibitors may be from about 0.1 to about 5% by weight, and others, the corrosion inhibitor may preferably be from about 0.5 to about 2% by weight of the composition.

The composition may optionally include an organic acid as the corrosion inhibitor alone or in combination with other corrosion inhibitors. Exemplary organic acids include, but are not limited to, citric acid, anthranilic acid, gallic acid, benzoic acid, malonic acid, maleic acid, fumaric acid, D,L-malic acid, isophthalic acid, phthalic acid, and lactic acid. In one embodiment, the organic acid is selected from the group consisting of gallic acid, isophthalic acid, and mixtures thereof. The organic acid may be present in amounts ranging from about 0% to about 5%, preferably about 0.1% to about 3%, and more preferably about 0.5% to about 2% by weight based on the total weight of the composition. The one or more organic acids may only be one or more of a mixture of corrosion inhibitors present in the composition. For example, in some embodiments the corrosion inhibitors may comprise a mixture of one or more organic acid(s) with one or more catechols and/or one or more thiazoles.

The composition may also include one or more of the following optional additives: surfactants, chelating agents, chemical modifiers, dyes, biocides, and other additives. Additives may be added to the composition described herein provided that such additives do not adversely affect the stripping and cleaning ability of the composition or the integrity of the underlying substrate. One type of additive that may be added to the compositions include additives to tune the electrochemical properties of the composition depending upon the metal compositions present on the substrate to be cleaned. One type of additive includes amino acids, such as taurine, glycine, and analine. If present, the amino acid or other electrochemical tuning component is present in the composition from about 0.001 to about 1% by weight of the total composition. In one embodiment of the invention, when the amino acid is present, the composition will be substantially free of or free of a corrosion inhibitor.

According to other embodiments of the invention, the composition includes about 10-20% by weight of one or more alkanolamines (e.g., MEA) or one or more morpholines or mixtures thereof based on the total weight of the composition; about 50-75% by weight of the one or more organic solvents (e.g., THFA) based on the total weight of the composition; about 0-1.5% by weight of a thiazole (e.g., ABT); about 0-2% by weight of one or more hydroxide (e.g., potassium hydroxide); and about 0-60% by weight water based on the total weight of the composition.

According to another embodiment of the invention, the composition comprises or consists essentially of about 5-30% by weight of a one or more alkanolamines (e.g., MEA) or one or more morpholines or mixtures thereof based on the total weight of the composition; about 20-80% by weight of a water soluble or water miscible organic solvent (e.g., THFA) based on the total weight of the composition (or mixtures of solvents); about 0.1-1.5% by weight of a corrosion inhibitor (e.g., ABT) or mixtures of corrosion inhibitors; about 0.1-2% by weight of one or more hydroxides (e.g., potassium hydroxide); about 0-5% by weight of an organic acid (e.g., gallic acid or isophthalic acid); and about 0-60% by weight water based on the total weight of the composition.

According to another embodiment of the invention, the composition includes from about 2 to about 8% or from about 2 to about 5% by weight of at least one alkanolamine (e.g., MEA) or at least one morpholine (e.g. N-(3-aminopropyl)morpholine) or mixtures thereof based on the total weight of the composition; from about 70 to about 94% or from about 75 to about 92% by weight of the organic solvent (may be mixtures of solvents) (e.g., THFA, glycol ether, and/or glycol or other alcohols) based on the total weight of the composition; from 0 to about 1.5% or from about 0.5 to about 1.5% by weight of a corrosion inhibitor (or mixtures of corrosion inhibitors) that may be a thiazole (e.g., ABT) or a imidazole; from 0 to about 5% or from about 0.5 to about 4% by weight of one or more hydroxides (e.g., potassium hydroxide or other metal hydroxide and/or tetraethylammonium hydroxide or other quaternary ammonium hydroxide); and from about 0 to about 20%, or from about 2 to about 17% by weight water based on the total weight of the composition.

According to another embodiment of the invention, the composition comprises or consists essentially of from about 2 to about 8% or from about 2 to about 5% by weight of one or more alkanolamines (e.g., MEA) or one or more morpholines (e.g. N-(3-aminopropyl)morpholine) or mixtures thereof based on the total weight of the composition; from about 70 to about 94% or from about 75 to about 92% by weight of the organic solvent (may be mixtures of solvents) (e.g., glycol ether, and/or glycol or other alcohols) based on the total weight of the composition; from 0 to about 1.5% or from about 0.5 to about 1.5% by weight of one or more corrosion inhibitors that may be a thiazole (e.g., ABT) and/or a benzimidazole and/or others; from 0 to about 5% or from about 0.5 to about 4% by weight of one or more hydroxides (e.g., potassium hydroxide or other metal hydroxide and/or tetraethylammonium hydroxide or other quaternary ammonium hydroxide); and from 0 to about 20%, or from about 2 to about 17% by weight water based on the total weight of the composition.

According to another embodiment of the invention, the composition includes from about 15 to about 20% by weight of one or more alkanolamines or one or more morpholines or mixtures thereof based on the total weight of the composition; from about 40 to about 65% by weight of the organic solvent or mixtures of solvents (for examples, DMSO or tri(propylene glycol) methyl ether or THFA) based on the total weight of the composition; from 1 to about 5.5% by weight of one or more corrosion inhibitors (for examples ABT, isophthalic acid, t-butyl catechol and 2-mercaptobenzimidazole); from about 0.05 (or about 0.08) to about 3.5% or from about 0.08 to about 0.4% by weight of one or more hydroxides (e.g., potassium hydroxide or other metal hydroxide and/or tetraethylammonium hydroxide or other quaternary ammonium hydroxide, such as choline hydroxide); and from about 10 to about 40% by weight water based on the total weight of the composition. In some embodiments, the hydroxide is a metal hydroxide, preferably potassium hydroxide, free from one or more quaternary ammonium hydroxides. In some embodiments, the hydroxide is present from about 0.05 to about 0.25 or from about 0.08 to about 0.22 or from about 0.1 to about 0.2% by weight of the composition.

According to another embodiment of the invention, the composition includes from about 2 to about 10%, or from about 2 to about 8%, or from about 2 to about 5%, or from about 3 to about 5% by weight of one or more alkanolamines or one or more morpholines or mixtures thereof based on the total weight of the composition; from about 65 to about 90% by weight, or from about 70 to about 95%, or from about 70 to about 85%, or from about 75 to about 92%, or from about 75 to about 82% by weight of the organic solvent or mixtures of solvents (for examples, at least one glycol ether, at least one glycol, or at least one alcohol, where the mixtures may be 2 or more of each of those types of solvents, e.g. 2 or 3 solvents) based on the total weight of the composition; from about 0.5 to about 2 or from about 0.5 to about 1.5% by weight of one or more corrosion inhibitors (for examples, ABT, isophthalic acid, t-butyl catechol and imidizoles, e.g., 2-mercaptobenzimidazole); from about 0.05 to about 4%, or from about 2 to about 4%, or from about 2.6 to about 4% by weight of one or more hydroxides (e.g., potassium hydroxide or other metal hydroxide and/or tetraethylammonium hydroxide or other quaternary ammonium hydroxide, such as choline hydroxide); and from about 2 to about 17%, or from about 8 to about 17% by weight water based on the total weight of the composition. In some embodiments, the hydroxide is at least one quaternary ammonium hydroxide, for example, tetraethylammonium hydroxide, and the composition may be free from metal hydroxides. In some embodiments, the quaternary ammonium hydroxide is selected from tetra ethyl ammonium hydroxide or tetra methyl ammonium hydroxide or mixtures thereof. The composition may comprise one or more morpholines and be free from alkanolamines. The composition may comprise solvent mixtures including at least one glycol ether and at least one glycol, or mixtures of at least one glycol ether, at least one glycol and at least one alcohol. Examples of the glycol ethers useful in mixtures of solvents include propylene glycol monophenyl ether and tripropylene glycol monobutyl ether, and examples of glycols include dipropylene glycol and an example of alcohols includes benzyl alcohol. In one embodiment the hydroxide is tetraethylammonium hydroxide and the corrosion inhibitor is 2-mercaptobenzimidazole which may be used in combination with the solvent mixtures.

Although certain combinations of the percentages of components have been specifically defined for some embodiments of the compositions, it is understood that narrower or broader ranges for particular components and specific relationships between the amounts and types of the components as defined elsewhere in this specification can be substituted into the specifically defined compositions to make alternative embodiments of the invention.

The cleaning composition of the present invention may be prepared by mixing the components together, simultaneously or sequentially, for example, in a vessel at room temperature until all solids have dissolved in the solvent-based or aqueous-based medium.

Preferably, the composition is basic with a pH greater than 7. In an exemplary embodiment, the composition has a pH of about 8.0 or higher, more preferably about 8.5 or higher. Accordingly, the composition may include a buffering agent, if necessary, to adjust the pH of the solution.

The compositions described herein are suitable for stripping, cleaning, or removing film resists, especially thick film resists. The resists may be comprised of any compositions known in the art. For example, the resist may include compositions suitable as positive or negative photoresists. The resist may comprise resins or polymers (e.g., novolak resins, styrenes, carbonates, epoxys, and acrylates), photoactive components (e.g., diazonaphtoquinone), and solvents (e.g., ethyl cellosolve acetate and diglyme). The resists may be “thick” film resists applied (in one or more applications) at a thickness, for example, up to about 150 μm (e.g., ultra-thick photoresists may have a thickness in the range of 20 to 100 μm). The resists may be highly cross-linked. The term “highly cross-linked” refers to resists with a high degree of linking between polymer chains in the resin or the resin with the photoactive components (e.g., greater than 50% cross-linked). The resists may be applied to a suitable substrate known in the art. For example, the substrate may be comprised of a metal or a compound thereof, such as tin/silver (Sn/Ag), lead (Pb), nickel (Ni), copper (Cu), titanium (Ti), titanium nitride, tantalum (Ta), tantalum nitride, aluminum (Al), alloys thereof, and the like. Semiconductor substrates also include silicon, silicate and/or inter-level dielectric material such as deposited silicon oxides, which may also come into contact with the cleaning composition.

According to one embodiment of the invention, a method of stripping or removing a film resist in a wet or dry process includes applying to the film resist a composition according to the present invention. The method may be conducted by contacting a film resist deposited on a substrate with the composition of the present invention. The film resist may be wet or dry (e.g., partially or fully cured). The actual conditions including the temperature, time, duration, etc. may depend on the nature and the thickness of the material to be removed. In general, the substrate may be contacted or dipped into a vessel or bath containing the composition at a temperature greater than about 35° C. (e.g., ranging from about 35° C. to 85° C.). Typical time periods for exposure of the substrate to the composition may range from, for example, 0.1 to 90 minutes, or 0.1 to 60 minutes, or 1 to 30 minutes, or 5 to 10 minutes. After contact with the composition, the substrate may be rinsed and then dried.

The contacting step may be carried out by any suitable means such as, for example, immersion, spray, or via a single wafer process; any method that utilizes a liquid for removal of photoresist, ash or etch deposits and/or contaminants can be used. The contacting step may be used in a wet or dry stripping process. The wet stripping technique may include submersing the substrate and resist in a bath. The dry stripping technique may include using the composition in combination with a chemically reactive or inert gas. In either process, the composition should be used to remove the resist from the substrate without corroding, dissolving, and/or dulling the surface of any metallic circuitry; chemically altering the inorganic substrate; and/or attacking the substrate itself.

The rinsing step may be carried out by any suitable means, for example, rinsing the substrate with de-ionized water by immersion or spray techniques. In preferred embodiments, the rinsing step is carried out employing a mixture of de-ionized water and/or a water miscible organic solvent such as, for example, isopropyl alcohol. In certain embodiments, a deionized water rinse or rinse containing deionized water with other additives may be employed before, during, and/or after contacting the substrate with the composition described herein.

The drying step may be carried out by any suitable means, for example, isopropyl alcohol (IPA) vapor drying or by centripetal force. Drying may be carried out under an inert atmosphere.

It will be appreciated by those skilled in the art that the cleaning composition of the present invention may be modified to achieve optimum removal of the resist film without damaging the substrate so that high throughput cleaning can be maintained in the manufacturing process. For example, one skilled in the art would appreciate that, for example, modifications to the amounts of some or all of the components may be made depending upon the composition of the substrate being cleaned, the nature of the resist to be removed, and the particular process parameters used.

Although the present invention has been principally described in connection with cleaning semiconductor substrates, the cleaning compositions of the invention can be employed to clean any substrate that includes resist films.

### EXAMPLES

The following examples are provided for the purpose of further illustrating the present invention but are by no means intended to limit the same. Compositions A-Z and A1-A3 are provided in Table 1 and A14-A19 are provided in Table 3 where the following acronyms are used:
NMP: N-methylpyrollidone;
DMSO: dimethylsulfoxide;
ABT: 2-aminobenzothiazole;
MBI: 2-mercaptobenzimidazole
MEA: monoethanolamine;
KOH: potassium hydroxide;
TBC: t-butylcatechol;
PG: propylene glycol;
DPM: di(propylene glycol) methyl ether;
THFA: tetrahydrofurfuryl alcohol;
APM: N-3-aminopropylmorpholine
t-PGME: tri(propylene glycol)methyl ether; and
DI water: deionized water.

TABLE 1

| Example A | | Example B | | Example C | |
|---|---|---|---|---|---|
| Choline hydroxide | 5.00 | Choline hydroxide | 3.00 | Choline hydroxide | 3.00 |
| NMP | 61.00 | DMSO | 61.00 | DMSO | 61.00 |
| ABT | 1.00 | ABT | 1.00 | ABT | 1.00 |
| isophthalic acid | 1.00 | isophthalic acid | 1.00 | isophthalic acid | 1.00 |
| TBC | 3.50 | TBC | 3.50 | TBC | 3.50 |
| MEA | 20.00 | MEA | 20.00 | MEA | 20.00 |
| KOH | 0.20 | KOH | 0.10 | KOH | 0.30 |
| DI Water | 8.30 | DI Water | 10.40 | DI Water | 10.20 |
| Example D | | Example E | | Example F | |
| Choline hydroxide | 5.00 | Choline hydroxide | 5.00 | NMP | 65.00 |
| | | | | aminobenzene | |
| NMP | 61.00 | DMSO | 61.00 | sulfonic acid | 0.60 |
| ABT | 1.00 | ABT | 1.00 | catechol | 5.00 |
| isophthalic acid | 1.00 | isophthalic acid | 1.00 | PG | 7.00 |
| TBC | 3.50 | TBC | 3.50 | MEA | 12.00 |
| MEA | 20.00 | MEA | 20.00 | KOH | 1.00 |
| KOH | 0.20 | KOH | 0.20 | DI Water | 9.40 |
| DI Water | 8.30 | DI Water | 8.30 | | |
| Example G | | Example H | | Example I | |
| choline hydroxide | 0.60 | choline hydroxide | 0.60 | choline hydroxide | 0.60 |
| DPM | 45.00 | DPM | 47.00 | DPM | 47.00 |
| ABT | 1.00 | ABT | 1.00 | ABT | 1.00 |
| TBC | 3.50 | Gallic acid | 1.50 | Gallic acid | 1.50 |
| KOH | 0.40 | KOH | 0.40 | KOH | 0.00 |
| MEA | 20.00 | MEA | 20.00 | MEA | 20.00 |
| isophthalic acid | 1.00 | isophthalic acid | 1.00 | isophthalic acid | 1.00 |
| DI Water | 28.50 | DI Water | 28.50 | DI Water | 28.90 |
| Example J | | Example K | | Example L | |
| DPM | 30.00 | DPM | 30.00 | DPM | 47.00 |
| ABT | 1.00 | ABT | 1.00 | ABT | 1.00 |
| Gallic acid | 1.50 | Gallic acid | 1.50 | Gallic acid | 1.50 |
| KOH | 0.00 | KOH | 0.40 | KOH | 0.00 |
| MEA | 15.00 | MEA | 20.00 | MEA | 20.00 |
| isophthalic acid | 1.00 | isophthalic acid | 1.00 | isophthalic acid | 1.00 |
| DI Water | 51.50 | DI Water | 46.10 | DI Water | 29.50 |
| Example M | | Example N | | Example O | |
| THFA | 20.00 | t-PGME | 20.00 | THFA | 55.00 |
| ABT | 1.00 | ABT | 1.00 | ABT | 1.00 |
| KOH | 0.40 | KOH | 0.40 | KOH | 0.20 |
| MEA | 55.00 | MEA | 55.00 | MEA | 20.00 |
| DI Water | 23.60 | DI Water | 23.60 | DI Water | 23.80 |
| Example P | | Example Q | | Example R | |
| THFA | 55.00 | t-PGME | 55.00 | t-PGME | 60.00 |
| ABT | 1.00 | ABT | 1.00 | ABT | 1.00 |
| KOH | 0.20 | KOH | 0.20 | KOH | 0.20 |
| MEA | 15.00 | MEA | 15.00 | MEA | 15.00 |
| DI Water | 28.80 | DI Water | 28.80 | DI Water | 23.80 |
| Example S | | Example T | | Example U | |
| THFA | 50.00 | t-PGME | 50.00 | t-PGME | 50.00 |
| ABT | 1.00 | ABT | 1.00 | ABT | 1.00 |
| KOH | 0.20 | KOH | 0.20 | KOH | 0.20 |
| MEA | 15.00 | MEA | 15.00 | MEA | 20.00 |
| DI Water | 33.80 | DI Water | 33.80 | DI Water | 28.80 |
| Example V | | Example W | | Example X | |
| THFA | 73.00 | THFA | 64.00 | THFA | 63.00 |
| ABT | 1.00 | ABT | 1.00 | ABT | 1.00 |
| KOH | 0.40 | KOH | 0.20 | KOH | 0.40 |
| MEA | 10.00 | MEA | 10.00 | MEA | 10.00 |
| PG | 14.00 | PG | 14.00 | PG | 14.00 |
| DI Water | 1.60 | DI Water | 10.80 | DI Water | 11.60 |
| Example Y | | Example Z | | Example A1 | |
| t-PGME | 63.00 | t-PGME | 73.00 | t-PGME | 55.00 |
| ABT | 1.00 | ABT | 1.00 | ABT | 1.00 |
| KOH | 0.40 | KOH | 0.40 | KOH | 0.20 |
| MEA | 10.00 | MEA | 10.00 | MEA | 20.00 |
| PG | 14.00 | PG | 14.00 | DI Water | 23.80 |
| DI Water | 11.60 | DI Water | 1.60 | | |

| Example A2 | | Example A3 | |
|---|---|---|---|
| THFA | 60.00 | THFA | 50.00 |
| ABT | 1.00 | ABT | 1.00 |
| KOH | 0.20 | KOH | 0.20 |
| MEA | 15.00 | MEA | 20.00 |
| DI Water | 23.80 | DI Water | 28.80 |

Based on the above compositions, the following results were obtained as summarized in Table 2. The “Thick Resist Film” column indicates whether the resist was completely removed (100% cleaned), if a slight residue of the resist remained (i.e., about 90% cleaned), or if the resist was only partially removed (partially cleaned) (i.e., from about 75 to 85% cleaned) and some resist remained on the substrate. The “Metal post” column designates if any damage occurred to the underlying substrate (post) where etching or corrosion is not desired and, thus, “not etched” indicates the desired outcome. Here, “slightly etched” refers to from less than about 10% to about 15%, and “etched” refers to at least about 60% corroded.

TABLE 2

| Strippers | Thick Resist Film | Metal post |
|---|---|---|
| Example A | Cleaned | Slightly etched |
| Example B | Cleaned | Not etched |
| Example C | Cleaned | Slightly etched |
| Example D | Cleaned | Etched (corroded) |
| Example E | Cleaned | Etched (corroded) |
| Example F | Cleaned | Etched (corroded) |
| Example G | Partially cleaned | Slightly etched |
| Example H | Partially cleaned | Slightly etched |
| Example I | Partially cleaned | Not etched |
| Example J | Partially cleaned | Not etched |
| Example K | Partially cleaned | Slightly etched |
| Example L | Slight residue | Not etched |
| Example M | Cleaned | Slightly etched |
| Example N | Cleaned | Slightly etched |
| Example O | Cleaned | Slightly etched |
| Example P | Cleaned | Not etched |
| Example Q | Cleaned | Not etched |
| Example R | Cleaned | Not etched |
| Example S | Cleaned | Not etched |
| Example T | Slight residue | Not etched |
| Example U | Slight residue | Not etched |
| Example V | Cleaned | Slightly etched |
| Example W | Slight residue | Not etched |
| Example X | Slight residue | Slightly etched |
| Example Y | Cleaned | Slightly etched |
| Example Z | Cleaned | Slightly etched |
| Example A1 | Cleaned | Not etched |
| Example A2 | Cleaned | Not etched |
| Example A3 | Cleaned | Not etched |
| Example A12 | Cleaned | Not etched |
| Example A13 | Cleaned | Not etched |

As is evident, all of the examples were effective in at least partial removal of the resist. Examples B, P, Q, R, S, A1, A2, and A3 performed the best, with complete cleaning and removal of the film resist and no damage or etching to the underlying metal post or substrate. Examples L, T, U, and W also worked well with only a slight residue of the resist remaining and no damage or etching to the metal post. Examples G, H, I, J, and K only partially cleaned or removed the resist, and Examples D, E, and F etched or corroded the underlying metal post. Examples C, M, N, O, V, Y, and Z were effective at cleaning the film resist, but slightly etched the metal post. These results indicate a balance of the alkanolamine, the organic solvent, and other optional ingredients produce superior results in both stripping and cleaning the film resist and minimizing or avoiding damage to the underlying substrate.

Examples P, Q, R, S, A1, A2, and A3, providing excellent results with complete cleaning of the film resist and no etching of the underlying metal post, included 15-20% by weight of monoethanol amine as the alkanolamine; 50-60% by weight of THFA or t-PGME as the organic solvent; 1% by weight of ABT as the corrosion inhibitor; 1% of potassium hydroxide (20%) as the hydroxide; and 23-33% by weight water.

Additional formulations were prepared as follows in Table 3 and most were tested in the same way as described above for the formulations tested above. The results are in Table 4.

TABLE 3

| | A4 | | |
|---|---|---|---|
| PROPYLENE GLYCOL MONOPHENYL | 45.60 | | |
| ETHER | | | |
| DIPROPYLENE GLYCOL | 45.60 | | |
| 2-Mercaptobenzimidazole | 1.00 | | |
| Tetramethylammonium hydroxide | 2.40 | | |
| ETHANOLAMINE | 3 | | |
| DIW | 2.4 | | |
| | A5 | A6 | A7 |
| PROPYLENE GLYCOL MONOPHENYL | 45.60 | 43.00 | 38.30 |
| ETHER | | | |
| DIPROPYLENE GLYCOL | 45.60 | 43.00 | 38.30 |
| 2-Mercaptobenzimidazole | 1.00 | 1.00 | 1.00 |
| Tetraethylammonium hydroxide | 0.96 | 2.00 | 3.88 |
| ETHANOLAMINE | 3 | 3 | 3 |
| DIW | 3.84 | 8.00 | 15.52 |
| | A8 | | |
| PROPYLENE GLYCOL MONOPHENYL | 38.30 | | |
| ETHER | | | |
| DIPROPYLENE GLYCOL | 38.30 | | |
| 2-Mercaptobenzimidazole | 1.00 | | |
| Tetraethylammonium hydroxide | 3.88 | | |
| N-(3-Aminopropyl)morpholine | 3 | | |
| DIW | 15.52 | | |
| | A9 | | |
| TRIPROPYLENE GLYCOL | 28.26 | | |
| MONOBUTYL ETHER (TPnB) | | | |
| BENZYL ALCOHOL | 23.55 | | |
| DIPROPYLENE GLYCOL | 37.68 | | |
| ETHANOLAMINE | 4.71 | | |
| 2-Mercaptobenzimidazole | 1.00 | | |
| Tetramethylammonium hydroxide | 2.40 | | |
| DIW | 2.40 | | |
| | A10 | | |
| TRIPROPYLENE GLYCOL | 25.35 | | |
| MONOBUTYL ETHER (TPnB) | | | |
| BENZYL ALCOHOL | 21.13 | | |
| DIPROPYLENE GLYCOL | 33.80 | | |
| ETHANOLAMINE | 4.22 | | |
| 2-Mercaptobenzimidazole | 1.00 | | |
| Tetraethylammonium hydroxide | 2.90 | | |
| DIW | 11.60 | | |
| | A11 | | |
| TRIPROPYLENE GLYCOL | 25.35 | | |
| MONOBUTYL ETHER (TPnB) | | | |
| BENZYL ALCOHOL | 21.13 | | |
| DIPROPYLENE GLYCOL | 33.80 | | |
| N-(3-Aminopropyl)morpholine | 4.22 | | |
| (APM) | | | |
| 2-Mercaptobenzimidazole | 1.00 | | |
| Tetraethylammonium hydroxide | 2.90 | | |
| DIW | 11.60 | | |
| | A12 | | |
| Taurine | 0.01 | | |
| tripropylene glycol monomethyl | 40.00 | | |
| ether | | | |
| KOH | 0.10 | | |
| Monoethanolamine | 20.00 | | |
| DI water | 39.89 | | |
| | A13 | | |
| t-PGME | 45.00 | | |
| Aminobenzothiazole | 1.00 | | |
| KOH | 0.10 | | |
| N-(3-Aminopropyl)morpholine | 15.00 | | |
| DI water | 38.90 | | |

TABLE 4

| | process temperature | process time | cleaning |
|---|---|---|---|
| formulations | (° C.) | (min) | performance |
| A4 | 60 | 15 | not clean |
| | 60 | 60 | notclean |
| | 75 | 60 | partial clean- |
| A5 | 75 | 60 | light residue |
| A6 | 75 | 60 | light residue |
| A7 | 75 | 30 | light residue |
| | 75 | 60 | clean |
| A8 | 75 | 30 | clean |
| A9 | 60 | 15 | not clean |
| | 60 | 60 | partial clean- |
| A10 | 75 | 30 | partial clean |
| A11 | 75 | 30 | clean |

Examples A4-A11 were effective in at least partial removal of the resist. Example A7, A8 and A11 performed the best with complete cleaning of the resist film.

| Example A14 | | Example A15 | | Example A16 | |
|---|---|---|---|---|---|
| THFA | 20.00 | t-PGME | 20.00 | t-PGME | 20.00 |
| ABT | 1.00 | ABT | 1.00 | ABT | 1.00 |
| KOH | 0.40 | KOH | 0.40 | KOH | 0.40 |
| APM | 55.00 | APM | 55.00 | APM | 25.00 |
| DI Water | 23.60 | DI Water | 23.60 | MEA | 30.00 |
| | | | | DI Water | 23.60 |
| Example A17 | | Example A18 | | Example A19 | |
| t-PGME | 40.00 | t-PGME | 40.00 | t-PGME | 40.00 |
| tannic acid | 3.00 | MBI | 3.00 | MBI | 3.00 |
| KOH | 1.00 | KOH | 0.10 | Imidazole | 2.00 |
| MEA | 20.00 | MEA | 20.00 | KOH | 0.10 |
| DI water | 36.00 | DI water | 36.90 | MEA | 20.00 |
| | | | | DI water | 34.90 |

These formulations were used to process wafer pieces at 75° C for 15 minutes. The observed results are summarized in the Table below.

| Strippers | Thick Resist Film | Metal Posts |
|---|---|---|
| Example A14 | Cleaned | Slightly etched |
| Example A15 | Cleaned | Slightly etched |
| Example A16 | Cleaned | Slightly etched |
| Example A17 | Cleaned | Slightly etched |
| Example A18 | Cleaned | Not etched |
| Example A19 | Cleaned (with very light | Not etched |
| | residues) | |

The foregoing examples and description of the preferred embodiments should be taken as illustrating, rather than as limiting the present invention as defined by the claims. As will be readily appreciated, numerous variations and combinations of the features set forth above can be utilized without departing from the present invention as set forth in the claims. Such variations are not regarded as a departure from the spirit and scope of the invention, and all such variations are intended to be included within the scope of the following claims.

1. (canceled)

2. (canceled)

3. (canceled)

4. The composition of claim 29 comprising:
about 2-8% by weight of said at least one alkanolamine or at least one morpholine or mixtures thereof;
about 70-94% by weight of said at least one organic solvent; and
about 8-17% by weight said water;
about 0.5-4% by weight of at least one hydroxide;
and about 0.5-1.5% by weight of at least one corrosion inhibitor.

5. The composition of claim 29 comprising:
about 2-5% by weight of said one or more alkanolamines or one or more morpholines or mixtures thereof;
about 75-92% by weight of the one or more organic solvents;
about 8-17% by weight water;
and further comprising about 0.5-4% of said one or more hydroxides; and
about 0.5-1.5% by weight of one or more corrosion inhibitors based on the total weight of the composition.

6. The composition of claim 29, wherein the at least one alkanolamine comprises monoethanol amine, N-methylethanolamine, or triethanolamine.

7. The composition of claim 29, wherein the at least one organic solvent is selected from the group consisting of glycol ethers, hydric alcohols or diols having 2 to 8 carbon atoms and benzyl alcohol.

8. The composition of claim 29, wherein the at least one organic solvent comprises tetrahydrofufuryl alcohol.

9. The composition of claim 29, where the at least one organic solvent is selected from the group consisting of propylene glycol mono phenyl ether, tri(propylene glycol) mono butyl ether, dipropylene glycol, tri(propylene glycol) methyl ether and mixtures thereof.

10. The composition of claim 29, wherein the composition is free of dimethyl acetamide.

11. The composition of claim 10, wherein the composition is free of dimethylsulfoxide or N-methylpyrrolidone.

12. (canceled)

13. The composition of claim 29, wherein the hydroxide is comprises potassium hydroxide.

14. The composition of claim 29, wherein the hydroxide comprises a one or more quaternary ammonium compounds.

15. The composition of claim 29 being substantially free of one or more of the following in any combination: dimethyl acetamide, potassium hydroxide or other metal hydroxide, fluorine, chlorine, oxidizer, H2O2 or nitric oxide.

16. The composition of claim 15 being substantially free of all of the following: dimethyl acetamide, fluorine, chlorine, oxidizer, H2O2 or nitric oxide.

17. The composition of claim 29 further comprising a corrosion inhibitor selected from the group consisting of thiazoles, organic acid salts, phenols, acids, triazoles, catechol, resorcinol, maleic anhydride, phthalic anhydride, catechol, pyrogallol, esters of gallic acid, carboxybenzotriazole, fructose, ammonium thiosulfate, glycine, tetramethylguanidine, iminodiacetic acid, dimethylacetoacetamide, trihydroxybenzene, dihydroxybenzene, salicyclohydroxamic, aminobenzosulfonic acid and mixtures thereof.

18. The composition of claim 29, wherein the corrosion inhibitor is aminobenzothiazole or 2-mercaptobenzimidizole.

19. The composition of claim 29 further comprising an organic acid selected from the group consisting of citric acid, anthranilic acid, gallic acid, benzoic acid, malonic acid, maleic acid, fumaric acid, D,L-malic acid, isophthalic acid, phthalic acid, lactic acid, tannic acid and mixtures thereof.

20. The composition of claim 29, wherein the composition has a pH of about 8.0 or higher.

21. (canceled)

22. (canceled)

23. (canceled)

24. (canceled)

25. (canceled)

26. The composition of claim 29, comprising N-(3-aminopropyl) morpholine; and the solvent is selected from the group consisting of propylene glycol monophenyl ether, tripropylene glycol monomethyl ether, benzyl alcohol, tripropylene glycol monobutyl ether and dipropylene glycol and mixtures thereof.

27. (canceled)

28. The method of claim 32 wherein the film resist has a thickness of up to about 150 μm.

29. A composition for removing a film resist wherein the composition comprises:
about 2-10% by weight of said at least one alkanolamine or at least one morpholine or mixtures thereof;
about 70-95% by weight of said at least one organic solvent; and
about 2-17% by weight said water;
about 0.05-4% by weight of at least one hydroxide;
and about 0.5-2% by weight of at least one corrosion inhibitor.

30. A composition for removing a film resist wherein the composition consisting essentially of:
about 2-10% by weight of said at least one alkanolamine or at least one morpholine or mixtures thereof;
about 70-95% by weight of said at least one organic solvent;
about 2-17% by weight said water;
about 0.05-4% by weight of at least one hydroxide;
and about 0.5-2% by weight of at least one corrosion inhibitor.

31. The composition of claim 29, wherein the composition comprises ethanolamine;
and the solvent is selected from the group consisting of propylene glycol monophenyl ether, tripropylene glycol monomethyl ether, benzyl alcohol, dipropylene glycol, tripropylene glycol monobutyl ether and mixtures thereof.

32. A method of stripping a film resist comprising:
applying to the film resist a composition comprising:
about 2-10% by weight of said at least one alkanolamine or at least one morpholine or mixtures thereof;
about 70-95% by weight of said at least one organic solvent;
about 2-17% by weight said water;
about 0.05-4% by weight of at least one hydroxide;
and about 0.5-2% by weight of at least one corrosion inhibitor.
